(19) United States
(12) Patent Application Publication
(10) Pub. No.: US 2012/0120703 A1
(43) Pub. Date: May 17, 2012

(54) MEMORY DEVICE WITH ASYMMETRICAL BIT CELL ARRAYS AND BALANCED RESISTANCE AND CAPACITANCE

(75) Inventors: Feng-Ming CHANG, Chia-Yi (TW); Chang-Ta YANG, Hsinchu (TW); Huai-Ying HUANG, Jhonghe (TW); Ping-Wei WANG, Hsin-Chu (TW)

(73) Assignee: TAIWAN SEMICONDUCTOR MANUFACTURING CO., LTD., Hsin-Chu (TW)

(21) Appl. No.: 12/946,136

(22) Filed: Nov. 15, 2010

(51) Int. Cl. G11C 5/02

(52) U.S. Cl. 365/51

(57) ABSTRACT

An SRAM or other semiconductor integrated circuit device includes a memory cell array having a layout portion in which a plurality of cell arrays extend along a substantially parallel pair of bit lines. Each cell array is separated from an adjacent cell array by a strap cell. As the cell arrays extend along the bit line pair, they form an alternating sequence of first and second cell arrays in which the first cell array is asymmetric with respect to the second cell array. In each first cell array, the bit line is coupled to a greater number of contacts and in each second cell array, the complementary bit line is coupled to a greater number of contacts. The first cell arrays may all include the same layout and orientation.

### TECHNICAL FIELD OF THE INVENTION

The present invention relates generally to semiconductor devices and more particularly to a memory cell layout for integrated circuits.

### BACKGROUND

Complementary metal-oxide-semiconductor (CMOS) technology is the dominant semiconductor technology used today for the manufacture of various integrated circuit devices including ultra-large-scale integrated (ULSI) circuits. Size reduction of the semiconductor structures has provided significant improvement in the speed, performance and circuit density of the integrated circuits and improvement in the cost per unit function of semiconductor chips, over the past few decades. The associated increase in integration levels has enabled the production of memory devices having smaller sizes and increased memories. Significant challenges, however, are faced as the sizes of CMOS devices continue to decrease.

Integrated circuits that serve as memory devices or include memory portions are very popular and serve a variety of functions in the electronics world. In particular, SRAM (static random access memory) devices are utilized in virtually every type of electronic device. Memory devices typically include layouts that utilize repeating bit cell arrays for design convenience. One common layout for an SRAM integrated circuit device favored in the semiconductor manufacturing industry utilizes repeating arrays of 6 T single port SRAM cells or 8 T dual port SRAM cells. These cells are favored because they represent an established and common design that provides high levels of integration and include 6 or 8 functional transistors in minimal area.

SRAM integrated circuit devices are commonly formed to include a layout that includes a repeating array of bit cells that are coupled together using a complementary bit line pair. Bit cells and bit cell arrays are generally not symmetric structures and when these cells are coupled according to conventional array construction using a set of complementary bit lines, one bit line encounters a greater number of contacts than the complementary bit line. Accordingly, an unbalanced resistance and capacitance results between the bit line and the complementary bit line.

When bit cells or arrays of bit cells extend lengthwise along a complementary bit line pair, strap cells are commonly provided between the bit cells or arrays of bit cells along the length of the complementary bit line pair. The strap cells provide well pickup and are generally formed in active areas inside wells and are regularly spaced along the bit line pair. The well straps are used for voltage pick-up and to provide well bias that prevents voltage drop along the pair of bit lines that could result in a difference in bit cell device voltages along the pair of bit lines as the bit lines travel along the bit cells or arrays of bit cells. The well straps allow for longer bit line pairs that traverse greater numbers of bit cells or bit cell arrays. If well straps are not used frequently, any bit cells that are spaced different distances from the well straps, will exhibit different behavior. Latch-up may occur and cause malfunction or performance degradation of the SRAM. The presence of these well straps, however, exacerbates the resistance and capacitance difference between the extended bit line and complementary bit lines, in active areas of the device and creates a capacitance mismatch in BEOL (back end of line) processing and assembling operations. This capacitance difference becomes increased as more strap cells are used, but conventional design rules generally require the presence of a strap cell between bit cells or arrays of bit cells that have a length of about 30 microns or greater along the direction of the bit line pairs.

One conventional attempt at addressing this problem includes adding wiring levels and re-routing wiring schemes but the additional vias and routing increase both resistance and capacitance in the complementary bit line, therefore worsening the mismatch between the bit lines and also increases the complexity of back end wiring.

In order to utilize the advantageous and known SRAM cell structures, then, an improved layout for SRAM array construction is needed to provide matching or similar resistance and capacitance of the complementary bit line pair.

### BRIEF DESCRIPTION OF THE DRAWING

The present invention is best understood from the following detailed description when read in conjunction with the accompanying drawing. It is emphasized that, according to common practice, the various features of the drawing are not necessarily to scale. On the contrary, the dimensions of the various features may be arbitrarily expanded or reduced for clarity. Like numerals denote like features throughout the specification and drawing.

FIGS. 1A and 1B are plan views showing a layout of a portion of a memory cell;

FIGS. 2A and 2B are plan views showing an exemplary arrangement of a layout of a memory cell device according to the invention; and

FIG. 3 is a plan view showing an exemplary arrangement of a layout of a memory cell device according to the invention.

### DETAILED DESCRIPTION

According to one aspect, provided is a memory cell device such as an SRAM or other memory device that includes a plurality of memory cell arrays extending along a bit line pair, i.e., a bit line and a complementary bit line. The memory cell arrays may be separated by strap cells as the memory cell arrays extend along the bit line pair, according to one exemplary embodiment. Memory cell arrays that are adjacent along the direction of the bit line pair, are asymmetrical about the strap cell that is interposed between the adjacent memory cell arrays. According to one exemplary embodiment, extending along a substantially parallel pair of bit lines is a plurality of memory cell arrays in which adjacent memory cell arrays are asymmetrical.

According to one exemplary embodiment, the memory cell arrays are arranged along the bit line pairs in an alternating series of first memory cell arrays and second memory cell arrays in which the first memory cell arrays are asymmetric with respect to the second memory cell arrays. According to one exemplary embodiment, each of the first memory cell arrays has the same layout and orientation. According to one exemplary embodiment, each of the second memory cell arrays has the same layout as one another and the same layout as the first memory cell arrays but are oriented oppositely with respect to the first memory cell arrays. According to one exemplary embodiment, each of the second memory cell arrays includes the same layout as one another and as the first memory cell arrays but are oriented 180 degrees with respect to adjacent first memory cell arrays.

The memory cell arrays may include one or a plurality of memory cells which may be any of various conventional or other SRAM memory cells laid out in “split word line” style such as 6 T single port SRAM cells, 8 T dual port SRAM cells or 8 T or 10 T dual port SRAM cells. Various other memory cells including conventional memory cells may be used in other exemplary embodiments and the memory cells generally include at least a transistor array such as including pass gate transistors. The memory cells may alternatively be referred to as bit cells and the memory cell arrays as bit cell arrays.

According to one exemplary embodiment in which first and second memory cell arrays alternate along the direction of the complementary bit lines, in a first memory cell array, a first number of contacts are disposed along the bit line and a second, different number of contacts are disposed along the complementary bit line and in the second memory cell array, the opposite is true: the first number of contacts are disposed along the complementary bit line and the second, different number of contacts are disposed along the bit line. It is understood that when a contact is stated to be disposed along a bit line or complementary bit line, the bit line or complementary bit line is coupled to the contact and the subjacent feature to which contact is provided.

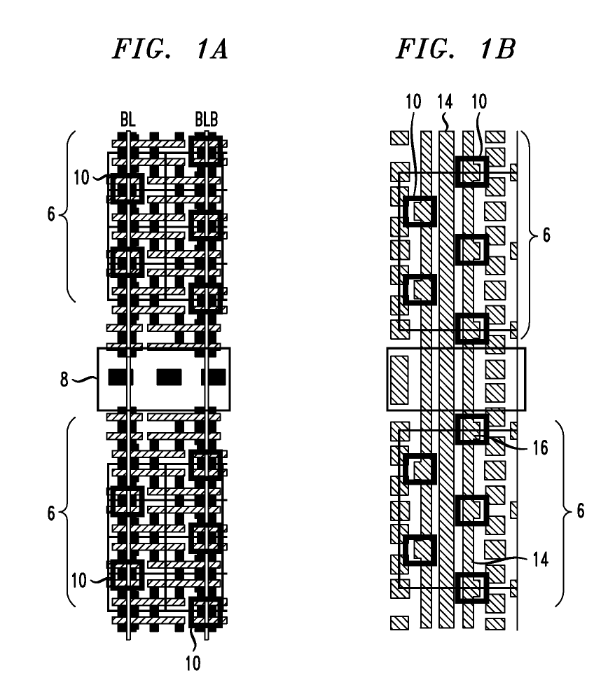

An exemplary SRAM array layout is shown in FIGS. 1A and 1B. FIG. 1A shows that the complementary bit line pair, BL 2 and BLB 4, run substantially parallel and along bit cell arrays 6 that are separated by strap cell 8. Each bit cell array 6 includes the same layout and orientation and the bit cell arrays 6 are symmetrical about the strap cell 8 that separates adjacent bit cell arrays 6. In each bit cell array 6, bit line BL 2 encounters only two contacts 10 whereas complementary bit line BLB 4 encounters three contacts 10. As this arrangement is repeated according to a conventional design scheme in which a great number of bit cell arrays 6 and strap cells 8 extend along BL 2 and BLB 4, the capacitance and resistance differences between the features along the complementary bit line pair, BL 2 and BLB 4, becomes significant. FIG. 1B shows the first metal level 14 associated with the conventional SRAM array layout shown in FIG. 1A including the additional first metal jogs 16 that accommodate associated contacts 10.

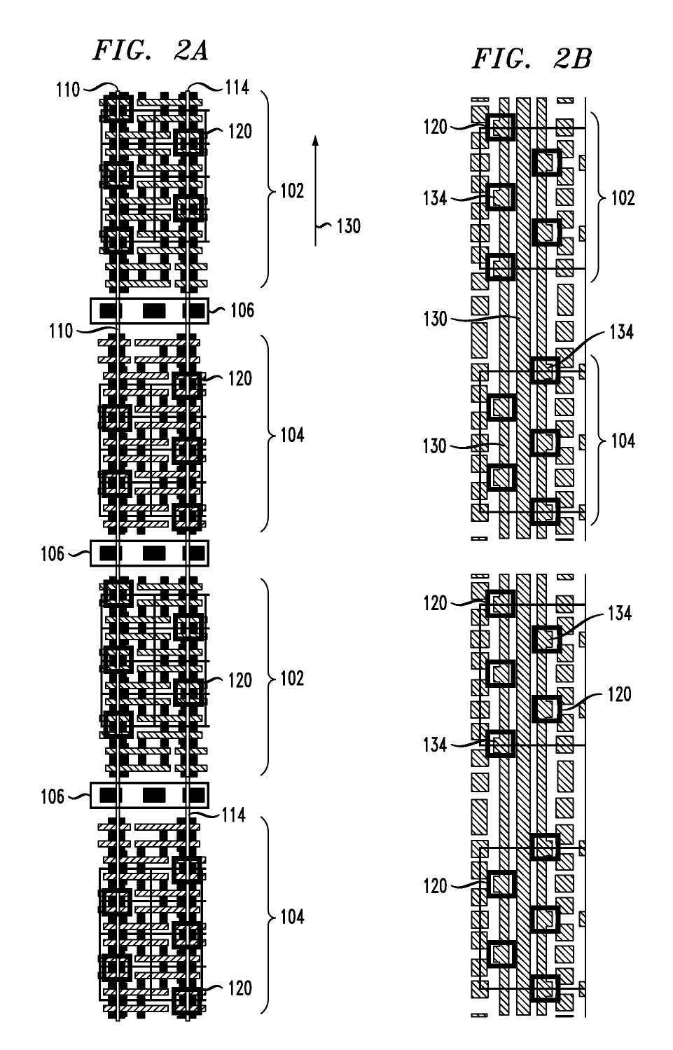

FIGS. 2A and 2B show an exemplary layout of bit cells that combine to form an integrated circuit device such as a memory device, according to the disclosure. FIG. 2A shows four (4) cell arrays that extend longitudinally along a bit line pair and FIG. 2B shows an exemplary metal layer used in conjunction with the cell arrangement shown in FIG. 2A. The four cell arrays illustrated in FIG. 2A are representative of a greater plurality of cell arrays that extend along the bit line pair.

FIG. 2A shows a plurality of cell arrays 102, 104 that extend along and are coupled by bit line 110 and complementary bit line 114 which are substantially parallel in the illustrated embodiment. Between each cell array 102, 104 is a strap cell 106. Strap cells are known to provide well pick-up and prevent voltage drop and are commonly known in the art. Various strap cells 106 may be used. First cell arrays 102 are identical to one another, i.e., they have the same layout and orientation. Second cell arrays 104 are also identical to one another, i.e., they have the same layout and orientation. Adjacent cell arrays, i.e., first cell array 102 and adjacent second cell array 104, are asymmetrical. The layout shown in FIG. 2A represents an alternating sequence of first cell arrays 102 and second cell arrays 104. First cell arrays 102 and second cell arrays 104 may be formed using conventional methods and materials. In the illustrated embodiment, it can be seen that first cell arrays 102 have the same layout as second cell arrays 104 but have the opposite orientation, i.e., first cell arrays 102 are rotated 180 degrees with respect second cell arrays 104 along direction 130 at least with respect to the arrangement of contacts 120. This is exemplary only. Each cell array 102, 104 may consist of a plurality of bit cells such as memory cells that include various transistor arrays and may be arranged in various relationships to form the respective first cell arrays 102 and second cell arrays 104. Either or both of first cell array 102 and second cell array 104 may consist entirely of or may include at least one SRAM memory cell such as a 6 T-SRAM cell or an 8 T-SRAM cell. According to one exemplary embodiment, the 6 T-SRAM cell may be a 6 T single port SRAM cell and the 8 T-SRAM cell may be an 8 T dual port SRAM cell. According to other exemplary embodiments, other SRAM cells laid out in split word line style may be used.

The plurality of cell arrays 102, 104 represent a portion of a semiconductor integrated circuit device such as a memory device such as an SRAM but the cell arrangement shown in FIGS. 2A, 2B may be used in various other types of semiconductor integrated circuit devices, according to other exemplary embodiments. Each of first cell arrays 102 and second cell arrays 104 include five contacts that are coupled to one of the bit lines, i.e., either to bit line 110 or complementary bit line 114 in the illustrated embodiment, but this is exemplary only and various other numbers of contacts 120 may be used in other exemplary embodiments. In first cell array 102, bit line 110 is coupled to a greater number of contacts 120, i.e., three contacts 120 than complementary bit line 114 which is only coupled to two contacts 120. In second cell array 104, in contrast, bit line 110 is only coupled to two contacts 120 whereas complementary bit line 114 is coupled to three contacts 120. In this manner, when an alternating series of first cell arrays 102 and second cells arrays 104 are arranged along a bit line pair such as bit line 110 and complementary bit line 114, each of the bit lines 110, 114 is coupled to the same number of contacts 120 as the bit line 110 and complementary bit line 114 extend along the alternating series of cell arrays 102, 104. In this manner, unbalanced capacitance and resistance between bit line 110 and complementary bit line 114 is avoided.

FIG. 2B is provided for clarity and shows a metal layer associated with the cell arrays 102, 104 shown in FIG. 2A and illustrates metal layer 130 to which contact may be provided through contacts 120. FIG. 2B more clearly illustrates that the number of metal jogs 134 differ between bit line 110 and complementary bit line 114 within one cell array 102 or 104, but that there are the same number of contacts and metal jogs 134 for each pair of adjacent and asymmetrical cell arrays, i.e., first cell array 102 and second cell array 104.

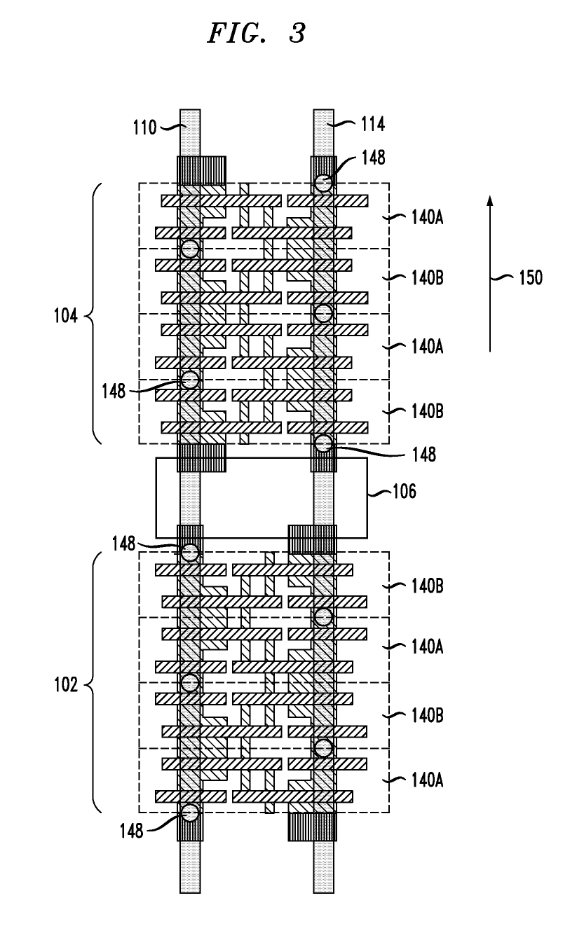

FIG. 3 shows further details of how exemplary asymmetric cell arrays may be formed from basic components, i.e. a plurality of bit cells according to one exemplary embodiment. FIG. 3 shows first cell array 102 and second cell array 104 separated by strap cell 106. Bit line 110 and complementary bit line 114 extend substantially parallel and couple the respective cell arrays 102, 104 across strap cell 106. First cell array 102 consists of four bit cells and second cell array 104 also consists of four bit cells. This is intended to be exemplary only and in other exemplary embodiments, each of first cell array 102 and second cell array 104 may consist of different numbers of individual bit cells. In the illustrated embodiment, first cell array 102 consists of four 6 T-SRAM cells. This is also intended to be exemplary only. According to the layout shown in FIG. 3, bit cells 140A and 140B include two orientations: bit cells 140A include orientation A and bit cells 140B include orientation B. Orientation A and orientation B are the mirror images of one another. In first cell array 102, first cell array 102 is formed of an alternating sequence of bit cells 140A and 140B beginning with a bit cell 140A along direction 150 and second cell array 104 also consists of an alternating sequence of first and second bit cells 140A, 140B and begins with bit cell 140B along direction 150.

Each cell 140A, 140B may represent a 6 T-SRAM cell such as a 6 T single port SRAM but other cell embodiments may be used to combine to form first cell array 102 and second cell array 104. Each 6 T-SRAM cell 140A, 140B includes six pass gate transistors and each set of two cells 140A, 140B includes three pass gate contacts 148.

According to another exemplary embodiment, the structure shown in FIG. 3 represents only a section of larger bit cell arrays disposed between strap cells. According to this exemplary embodiment, first cell array 102 and second cell array 104 may represent an adjacent portion of a larger bit cell array, i.e., the portion of a larger bit cell array adjacent strap cell 106. According to this exemplary embodiment, there may be other bit cell sections above second cell array 104 and below first cell array 102 according to the illustration, before the next strap cell 106 is encountered. According to this layout, in which a larger bit cell array includes additional features between strap cells, an advantage provided is that the sections of the respective cell arrays on either side of the strap cell, are asymmetrical and provide the same resistance and capacitance balancing as other exemplary embodiments.

According to one aspect of the disclosure, a memory cell device is provided. The memory cell device comprises a plurality of memory cell arrays separated by strap cells and coupled across the strap cells by both a bit line and a complementary bit line, wherein adjacent memory cell arrays are asymmetrical about the strap cell interposed between the adjacent memory cell arrays. The plurality of memory cell arrays may comprise an alternating sequence of first memory cell arrays and second memory cell arrays in which each first memory cell array has the same layout and orientation.

Also provided by the disclosure is a memory cell device comprising a plurality of bit cell arrays extending along the bit line and a substantially parallel complementary bit line. Each bit cell array includes a plurality of transistors therein. The plurality of bit cell arrays comprises an alternating sequence of first bit cell arrays and second bit cell arrays in which each first bit cell array has the same layout and orientation. The first bit cell arrays include a greater number of contacts along and coupled to the bit line and the second bit cell arrays include a greater number of contacts along and coupled to the complementary bit line.

The disclosure also provides a memory cell device comprising a plurality of memory cell arrays arranged along a bit line and a substantially parallel complementary bit line. Each memory cell array is separated from an adjacent memory cell array by a strap cell. Each memory cell array comprises a section of one or more memory cells adjacent each strap cell, each section including a transistor array. Respective sections on opposite sides of each strap cell are asymmetrical about the strap cell.

The preceding merely illustrates the principles of the disclosed invention. It will thus be appreciated that those skilled in the art will be able to devise various arrangements which, although not explicitly described or shown herein, embody the principles of the disclosure and are included within the spirit and scope of the invention. Furthermore, all examples and conditional language recited herein are principally intended expressly to be only for pedagogical purposes and to aid in understanding the principles of the disclosure and the concepts contributed to furthering the art, and are to be construed as being without limitation to such specifically recited examples and conditions. Moreover, all statements herein reciting principles, aspects, and embodiments of the disclosure, as well as specific examples thereof, are intended to encompass both structural and functional equivalents thereof. Additionally, it is intended that such equivalents include both currently known equivalents and equivalents designed or developed in the future, i.e., any elements developed that perform the same function, regardless of structure.

This description of the exemplary embodiments is intended to be read in connection with the figures of the accompanying drawing, which are to be considered part of the entire written description. In the description, relative terms such as “lower,” “upper,” “horizontal,” “vertical,” “above,” “below,” “up,” “down,” “top” and “bottom” as well as derivatives thereof (e.g., “horizontally,” “downwardly,” “upwardly,” etc.) should be construed to refer to the orientation as then described or as shown in the drawing under discussion. These relative terms are for convenience of description and do not require that the device be constructed or operated in a particular orientation. Terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise.

The appended claims should be construed broadly, to include other variants and embodiments of the disclosure, which may be made by those skilled in the art without departing from the scope and range of equivalents of the invention.

What is claimed is:

1. A memory cell device comprising a plurality of memory cell arrays separated by strap cells and coupled across said strap cells by both a bit line and a complementary bit line, wherein adjacent memory cell arrays are asymmetrical about said strap cell interposed between said adjacent memory cell arrays.

2. The memory cell device as in claim 1, wherein said plurality of memory cell arrays separated by strap cells and coupled across said strap cells by both a bit line and complementary bit line, include an alternating sequence of first memory cell arrays and second memory cell arrays in which each said first memory cell array has the same layout and orientation.

3. The memory cell device as in claim 2, wherein said first memory cell arrays each include a first number of contacts along and coupled to said bit line and a second number of contacts along and coupled to said complementary bit line and said second memory cell arrays each includes said first number of contacts along and coupled to said complementary bit line and said second number of contacts along and coupled to said bit line.

4. The memory cell device as in claim 3, wherein said bit line and said complementary bit line are substantially parallel.

5. The memory cell device as in claim 3, wherein said contacts comprise pass gate transistor contacts.

6. The memory cell device as in claim 2, wherein said second memory cell arrays each have the same layout and opposite orientation as said first memory cell arrays.

7. The memory cell device as in claim 6, wherein each said first memory cell array includes an alternating sequence of first and second memory cells beginning with one said first memory cell, and each said second memory cell array includes said alternating sequence of memory cells beginning with one said second memory cell, along a direction of said a bit line and said complementary bit line.

8. The memory cell device as in claim 2, wherein said second memory cell arrays each have the same layout as said first memory cell arrays and are rotated 180° with respect to said first memory cell arrays.

9. The memory cell device as in claim 8, wherein said bit line and said complementary bit line are substantially parallel.

10. The memory cell device as in claim 1, wherein each said memory cell array comprises a transistor array.

11. The memory cell device as in claim 1, wherein said memory cell device comprises an SRAM (static random access memory) device and each said memory cell array includes at least one 6 T single port SRAM cell.

12. The memory cell device as in claim 1, wherein said memory cell device comprises an SRAM (static random access memory) device and each memory cell of said memory cell arrays, comprises a 6 T SRAM cell.

13. A memory cell device comprising a plurality of bit cell arrays extending along a bit line and a substantially parallel complementary bit line;
each said bit cell array including a plurality of transistors therein; and
said plurality of bit cell arrays comprising an alternating sequence of first bit cell arrays and second bit cell arrays in which each said first bit cell array has the same layout and orientation and said first bit cell arrays include a greater number of contacts disposed along and coupled to said bit line than disposed along said complementary bit line and second bit cell arrays include a greater number of contacts disposed along and coupled to said complementary bit line than disposed along said bit line.

14. The memory cell device as in claim 13, wherein said contacts comprise pass gate transistor contacts.

15. The memory cell device as in claim 13, wherein each said bit cell array comprises at least one 6 T single port SRAM (static random access memory) cell.

16. The memory cell device as in claim 13, further comprising a plurality of strap cells, each interposed between adjacent bit cell arrays.

17. A memory cell device comprising:
a plurality of memory cell arrays arranged along a bit line and a substantially parallel complementary bit line, each said memory cell array separated from an adjacent said memory cell array by a strap cell;
each said memory cell array comprising a section of one or more said memory cells adjacent each said strap cell, each said section including a transistor array; and
wherein respective sections on opposite sides of each said strap cell are asymmetrical about said strap cell.

18. The memory cell device as in claim 17, wherein each said section comprises a pair of said memory cells.

19. The memory cell device as in claim 17, wherein, for each said strap cell, a first said section on one side of said strap cell includes a first number of contacts along said bit line and a second number of contacts along said complementary bit line and a second said section on an opposite side of said strap cell includes said first number of contacts along said complementary bit line and said second number of contacts along said bit line.

20. The memory cell device as in claim 19, wherein said contacts comprise pass gate transistor contacts.
